(19) United States
(12) Patent Application Publication
(10) Pub. No.: US 2026/0287900 A1
(43) Pub. Date: Sep. 24, 2026

(54) DISPLAY-COMBINER FOR AUGMENTED REALITY AND METHODS THEREOF

(71) Applicant: KDH Advanced Research Pty Ltd, Balwyn North (AU)

(72) Inventors: Ranjith RAJASEKHARAN UNNITHAN, Balwyn North (AU); Younger Wei-Young LIANG, Balwyn North (AU)

(21) Appl. No.: 19/677,717

(22) Filed: May 14, 2026

Related U.S. Application Data
(63) Continuation of application No. PCT/AU2024/051212, filed on Nov. 15, 2024.

(30) Foreign Application Priority Data
Nov. 15, 2023 (AU) 2023903679

(51) Int. Cl. G02B 27/01; G02B 1/04; G03F 7/00

(52) U.S. Cl. CPC G02B 27/0172; G03F 7/0002; G02B 1/04; G02B 2027/0123; G02B 2027/013; G02B 2207/101

(57) ABSTRACT

This disclosure concerns a display-combiner for creating a virtual image observable by a receiver, comprising:
a) a lens having a first surface;
b) a dielectric metasurface adjacent to the first surface, the dielectric metasurface having a planar cross-sectional area extending over at least a portion of the first surface; and
c) a micro-display unit configured to provide circularly polarised red, green and blue light to the dielectric metasurface;
   wherein the dielectric metasurface is a nanostructured polymer film configured to vary a phase profile of the circularly polarised red, green and blue light at each nanostructure in order for the polarised light to be reflected and focused as the virtual image to be observed by the receiver.

### CROSS-REFERENCES TO RELATED APPLICATIONS

This application is a continuation application of International Patent Application No. PCT/AU2024/051212 entitled “Display-Combiner for Augmented Reality and Methods Thereof,” filed on Nov. 15, 2024, which claims priority to Australian Patent Application No. 2023903679, filed on Nov. 15, 2023, each of which are herein incorporated by reference in their entirety for all purposes.

### TECHNICAL FIELD

The present invention relates, in general terms, to multifunctional metasurface display for augmented reality and the methods of fabrication thereof.

### BACKGROUND

Augmented Reality (AR) is an emerging technology that enables the seamless overlay of the real world with computer generated virtual images in such a way that the virtual content is aligned with real world objects. The main part of any AR device is a see-through display-combiner through which a viewer can see virtual content and real-world objects (example, Google glass, FIG. 1a). The power of AR technology is now being targeted in a wide range of application domains such as (a) new AR motor cycle visor; where the speed and images from side cameras are projected in front of the eyes to reduce accidents (2117 lives lost and more than 10,000 riders and pillions have seriously injured in Australia in motorcycle accidents from 2010-2019) (b) medical surgery; where the AR technology will project real scans of organs (diagnosis) on patent's real organ during surgery for improving accuracy and saving time (c) education; recent case studies have reported that children with special learning needs found to have a more positive learning experience with AR due the ability to see the image of an actual object when an instructor is teaching (d) entertainment; AR tourism and storytelling by recreating past scenes through AR in a historical site.

Despite AR promising to provide breakthrough visual experience in numerous applications, widespread adoption is limited due to discomfort, eyestrain and cumbersome devices (FIG. 1a). This is mainly caused by the physical form of current AR see-through display-combiners, which require the viewer to look through thick cube reflectors, inability to focus the virtual images on the retina while seeing the real world scenes (called vergence accommodation conflict), a limited field of view (FOV), and a small eye box that limits area where virtual image is visible. Such drawbacks are prohibiting market growth that has the potential to reach US$100 billion by 2025.

It would be desirable to overcome or ameliorate at least one of the above-described problems.

### SUMMARY

The present invention provides a display-combiner for creating a virtual image observable by a receiver, comprising:
a) a lens having a first surface;
b) a dielectric metasurface adjacent to the first surface, the dielectric metasurface having a planar cross-sectional area extending over at least a portion of the first surface; and
c) a micro-display unit configured to provide circularly polarised red, green and blue light to the dielectric metasurface;
   wherein the dielectric metasurface is a nanostructured polymer film configured to vary a phase profile of the circularly polarised red, green and blue light at each nanostructure in order for the polarised light to be reflected and focused as the virtual image to be observed by the receiver.

In some embodiments, the first surface of the lens is adjacent to the receiver.

In some embodiments, the lens is a flat lens, converging lens or a diverging lens.

In some embodiments, the converging lens is a double convex lens, a plano-convex lens or a converging meniscus lens.

In some embodiments, the dielectric metasurface is adhered to the lens.

In some embodiments, the dielectric metasurface comprises at least three arrays of nanostructures, each of the at least three arrays of nanostructures configured to independently vary the phase profile of each of the circularly polarised red, green and blue light.

In some embodiments, the dielectric metasurface comprises four arrays of nanostructures, each of the four arrays of nanostructures configured to independently vary the phase profile of each of the circularly polarised red, green, blue and green light.

In some embodiments, the nanostructures in the at least three arrays of nanostructures are superimposed on each other.

In some embodiments, the nanostructures in the at least three arrays of nanostructures are arrayed periodically or aperiodically.

In some embodiments, the nanostructures in the at least three arrays of nanostructures are arranged in a Bayer pattern or a random pattern.

In some embodiments, the at least three arrays of nanostructures are independently characterised by an emitted light with a hyperboloidal or parabolic phase profile.

In some embodiments, the dielectric metasurface is configured to vary the phase profile of a cross polarisation component of the circularly polarised red, green and blue light.

In some embodiments, the phase profile of a co-polarisation component of the circularly polarised red, green and blue light is unaltered.

In some embodiments, the nanostructures are each characterised by an orientation angle (θ) relative to each other. In some embodiments, the nanostructures are each characterised by an orientation angle (θ) dependent on its position on the dielectric metasurface.

In some embodiments, the nanostructures are each characterised by an orientation angle (θ) according to Formula (I):

$$Δ θ ( x , y ) = \frac{2 π}{λ} ( \sqrt{{x}^{2} + {y}^{2} - {f}^{2}} - f ) + \frac{2 π}{λ} x sin ( ∅ ) \qquad ( I )$$

wherein
x and y refers to a position of the nanostructure on the dielectric metasurface;
f is a focal length;
Ø is an oblique incidence of circularly polarised light; and
Λ is a wavelength of the circularly polarised light.

In some embodiments, the orientation angle of a nanostructure relative to another neighbouring nanostructure is about 0° to about 10°.

In some embodiments, each of the nanostructures is independently characterised by a morphology selected from a square, rectangle, ellipse, cross, hole, coaxial, ring, slit, or circle.

In some embodiments, the nanostructures are rectangles.

In some embodiments, each of the nanostructures is independently characterised by a longitudinal axis of about 20 nm to about 380 nm.

In some embodiments, each of the nanostructures is independently characterised by a transverse axis of about 20 nm to about 380 nm.

In some embodiments, when the array of nanostructures is configured to reflect and focus polarised red light, each of the nanostructure is characterised by a length of about 220 nm to about 300 nm.

In some embodiments, when the array of nanostructures is configured to reflect and focus polarised red light, each of the nanostructure is characterised by a width of about 20 nm to about 60 nm.

In some embodiments, when the array of nanostructures is configured to reflect and focus polarised red light, each of the nanostructure is characterised by a height of about 250 nm to about 350 nm.

In some embodiments, when the array of nanostructures is configured to reflect and focus polarised green light, each of the nanostructure is characterised by a length of about 370 nm to about 420 nm.

In some embodiments, when the array of nanostructures is configured to reflect and focus polarised green light, each of the nanostructure is characterised by a width of about 60 nm to about 100 nm.

In some embodiments, when the array of nanostructures is configured to reflect and focus polarised green light, each of the nanostructure is characterised by a height of about 250 nm to about 350 nm.

In some embodiments, when the array of nanostructures is configured to reflect and focus polarised blue light, each of the nanostructure is characterised by a length of about 300 nm to about 370 nm.

In some embodiments, when the array of nanostructures is configured to reflect and focus polarised blue light, each of the nanostructure is characterised by a width of about 100 nm to about 150 nm.

In some embodiments, when the array of nanostructures is configured to reflect and focus polarised blue light, each of the nanostructure is characterised by a height of about 250 nm to about 350 nm.

In some embodiments, the nanostructures are characterised by a pitch (spacing between nanostructures) of about 20 nm to about 700 nm.

In some embodiments, the nanostructures comprises a dielectric material and/or a metal, or is coated with a dielectric material and/or a metal.

In some embodiments, the dielectric material and/or a metal is selected from titanium dioxide, silicon dioxide, silicon, germanium, magnesium fluoride, silver, gold, aluminium, and copper.

In some embodiments, the polymer film comprises polydimethylsiloxane (PDMS), polystyrenes, polycarbonates, cyclic olefin copolymer, polyesters or a combination thereof.

In some embodiments, the polymer film is characterised by a thickness of about 1 μm to about 10 mm.

In some embodiments, the dielectric metasurface is characterised by a transparency of at least 90%.

In some embodiments, the micro-display unit provides polarised light to the metasurface at an oblique angle.

In some embodiments, the polarised light is right circular polarised.

### BRIEF DESCRIPTION OF THE DRAWINGS

Embodiments of the present invention will now be described, by way of non-limiting example, with reference to the drawings in which:

FIG. 1 shows (a) Google glass showing the cube reflector based AR display-combiner; (b) a schematics of the AR see-through display-combiner where polarised light (images) from a micro-display projector is directed at an oblique incident to a dielectric metasurface with multiple optical functions such as reflecting and focusing the images into eyes (virtual images) while being transparent to the lights from real objects; (c) an application of AR see-through display-combiner in spectacles.

FIG. 2 shows different AR display-combiner technologies (a) Cube reflector with magnifier [Google Glass, Kopin Solos AR] (b) Curved partially reflecting mirror [Dream Glass AR] (c) Curved cube [NED AR] (d) partially reflecting gold films (black dotted line) inside glass (Lumus AR) (e) Hologram based reflectors.

FIG. 3 shows a schematics of how the arrays of nanostructures are combined to provide a virtual image.

FIG. 4 shows a schematic of the fabrication of the metasurface.

FIG. 5 shows an example of a micro-display unit.

FIG. 6 shows a plot of phase change for cross polarised and co-polarised red, green and blue light.

### DETAILED DESCRIPTION

The basic units of an existing AR display consist of a micro-display unit (integrated with processors, electronics and rechargeable mini-batteries) for feeding images, coupling and magnifying optics to magnify the images from the microdisplay and to tune the location of the virtual image in front of the eyes, and an AR see-through display-combiner to overlay the images from micro-display and physical world (FIG. 2). The AR devices are categorised based on the different types of see-through display-combiners. Various approaches for the combiner designs in the literature for near-eye see-through displays include freeform optical prisms, curved mirrors, projection systems, hybrid reflective-refractive systems, optical waveguides and hologram (see FIG. 2 for some examples).

Commercial products in the market using these type of see-through display combiner technologies (FIG. 2) include Google glass, Kopin Solos, Dream Glass, NED AR, Lumus and Microsoft Hololens.

All of these technologies can cause eye strain and discomfort. The cube or curved reflectors based display-combiner technology offers the simplest solution to AR glasses but with issues caused by larger form-factor, limited field of view and eye box. The curved mirror also distorts the see-through images from the real world (FIG. 2b). NED AR introduced a curved prism to correct the see-through image distortion as shown in FIG. 2c. FIG. 2d shows Lumus AR glass technology where a glass waveguide carries the light (image) from a micro-display using multiple reflections and then uses partial reflecting mirrors (shown by the black dotted line) to reflect the image. Here, the see-through effect is compromised as the reflectance of each partial mirror based display-combiner (black dotted lines in FIG. 2d) is adjusted to distribute light over a wide eye box. Furthermore, this promising design suffers from low intensity of virtual images due to its inability to increase reflection without reducing transmission (example, increasing thickness of coatings to increase reflectivity reduces transmission), and also sacrifices the FOV by limiting angular range. Also, there is a discontinuity in viewing images when the eyeball moves due to the discontinuity of the reflectors. The hologram based design was demonstrated, but is limited because it is wavelength (colour) sensitive.

More recently, research has started to address the major limitations of the existing AR see-through displays such as eye strain and convergence accommodation conflict, limited FOV, small eye box and low intensity of virtual images in bright outdoor light. New grating-based flat diffractive optics combiners was reported. However, the gratings based combiners are wavelength sensitive (the design can be optimized to one single colour). They use only first order diffraction order (zero order and other orders are lost) for the virtual image resulting in lower brightness of virtual images. To overcome the wavelength sensitivity, a grating based waveguide combiner architecture using a three layer diffraction planar stack (each stack for red, green and blue colours) is used in the Microsoft HoloLens 1MR headset but the cost is a thick display-combiner. Thus, the design has limited FOV, causes eye strain (vergence conflict) and discomfort.

The major hurdles to improve the optical performances of the AR displays are the performance limitations of conventional optical systems, reflective, refractive, diffractive or holographic displays resulting in narrow FOV and bulky form factor due to low numerical aperture (NA) and large thickness of the optical display-combiners. Furthermore, each optical function needs a separate optical component, which can make the design bulky. To overcome some of these limitations, optical metasurfaces for AR displays may be used. The metasurfaces are planar artificial surfaces with subwavelength-scale thickness or features (called meta atoms) that provides control over optical fields and properties. As meta atoms with different sizes and shapes act as a polariser because they are individually polarisation sensitive, the same meta atoms may be arranged in a group to get a combined hyperboloidal phase profile to act as a lens so that the design can be lens-polariser combination, while being transparent.

Metasurfaces may increase the performance of AR. For example, it was shown that a metasurface waveguide based AR display can have enhanced FOV and reduced eye strain. However, this display cannot produce full colours and laser scanners are required for image production. A dynamic meta-system for AR holographic display based on liquid crystals was previously reported, but it was not able to produce full colours (holograms are wavelength sensitive) and suffered from vergence accommodation conflict. A metalens eye piece operating in transmission mode was reported, but this eye piece requires additional waveplate on the display-combiner that reduces the transmission and also increases the display-combiner design complexity.

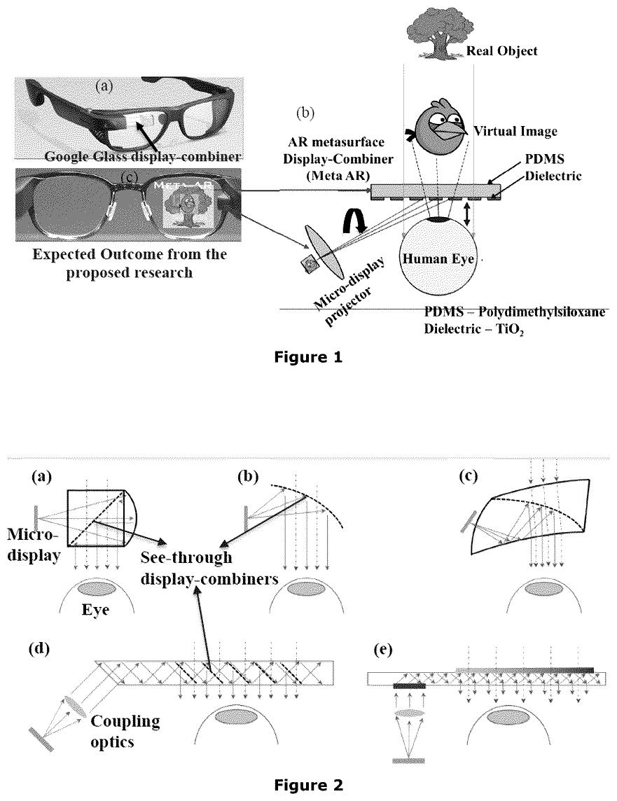

Additionally, existing cube reflector or flat reflector-based AR displays partially reflects the image from a micro-display unit into the eye to form a virtual image in front of the viewer, allowing the light from real scenes pass through (FIG. 1). The eye has to focus both the virtual image and real image placed at different distances. When the real scenes are far away from the virtual image location, it creates strain in eye, called vergence accommodation conflict. Furthermore, the FOV is limited and causes discomfort due to the thickness of combiner optics. Since the partial reflector must reflect and transmit the light simultaneously, the reflectivity of the reflector is often made much less than 20 percentage to avoid blocking the light transmitting through from real objects. This has also resulted in low intensity for virtual images with reduced clarity in outdoor bright conditions.

To reduce vergence accommodation conflict and to increase FOV of the display-combiner, a convex lens with a suitable focal length may be placed between eye and the display-combiner. This will focus the virtual image into eye (like a Maxwellian system) and hence eye needs to focus only transmitted light from real scenes which will considerably reduce the eye strain and also can increase FOV. However, the lens also introduces power to the transmitted light (see-through objects will also be enlarged) and will make the combiner bulkier and more complex.

The present invention provides a multifunctional metasurface based AR display-combiner (Meta AR) that is configured to reflect and focus polarised lights (images from a micro-display) into eyes, while being transparent to unpolarised light from the real scenes. The display substantially reduces eye strain (virtual image focusing), removes discomfort (thin and flat), large FOV and eye box (due to large area metasurface) and improved brightness due to polarisation sensitive reflection.

Accordingly, the present invention provides a display-combiner for creating a virtual image observable by a receiver, comprising:
a) a lens having a first surface;
b) a dielectric metasurface adjacent to the first surface, the dielectric metasurface having a planar cross-sectional area extending over at least a portion of the first surface; and
c) a micro-display unit configured to provide circularly polarised red, green and blue light to the dielectric metasurface;
   wherein the dielectric metasurface is a nanostructured polymer film configured to vary a phase profile of the circularly polarised red, green and blue light at each nanostructure in order for the polarised light to be reflected and focused as the virtual image to be observed by the receiver.

This work provides meta-surfaces to make flat AR display-combiners with multiple optical properties combined together. It addresses the limitations of existing AR combiner technologies using conventional optical elements improving functionality, comfort and size. AR glass has unique, optical performance requirements that are extending the boundaries of meta-surface research. For example, meta-lenses operating in transmission mode demonstrated co-polarized light, which was considered as ‘unwanted noise’ along with focused light. Herein, however, this ‘unwanted noise’ is exploited using a new design to improve transparency. For example, two independent elements, such as the filter and microlens can be applied on each nanostructure (pixel), in order to replace image sensors in a flat lens-colour filter combination.

Also, the functionalities of several distinct optical devices, such as polarisers, waveplates, lenses, and light modulators, can efficiently be combined into a single design to make flat and compact devices.

Specifically, the display-combiner may be a thin and flat AR see-through display-combiner using dielectric metasurfaces, with combined optical functionalities to exploit the full potential of the AR technology (FIG. 1b). The display-combiner may reflect and focus polarised lights from a micro-display projector into the eyes (virtual images), while is also transparent to unpolarised light from real objects as shown in FIG. 1b. The metasurfaces may be planar optical elements made of artificially fabricated subwavelength structures (meta atoms). The meta atoms may be of different sizes and shapes and may be arranged periodically or aperiodically/irregularly to obtain tailored multiple optical functions for manipulating the light.

The AR see-through display-combiner is comfortable enough to be worn for long periods without eye strain (no vergence accommodation conflict), with large eye box, field of view and without discomfort due to its thin and flat structure (FIG. 1c). As the AR see-through display-combiner resembles a normal daily use spectacle, it may facilitate the use/integration of the AR system in medical devices for surgery, classroom teaching and also can be easily integrated with helmet visors for making AR motorcycle helmets.

The display-combiner comprises a lens, the lens having a first surface. The lens may be a lens of a pair of glasses. In this way, the display combiner may be provided to a pair of glasses. The display-combiner also comprises a dielectric metasurface adjacent to the first surface of the lens. The dielectric metasurface has a planar cross-sectional area extending over at least a portion of the first surface of the lens. The dielectric metasurface may extend over a substantial area of the lens, or cover the whole area of the lens. The display-combiner also comprises a micro-display unit. The micro-display unit is configured to provide circularly polarised light, and in particular at least red, green and blue light to the dielectric metasurface. The micro-display unit may provide light of other colours as desired.

The dielectric metasurface is a nanostructured polymer film. In this regard, the dielectric metasurface is a polymer film comprising an array of nanostructures. The dielectric metasurface is configured to vary a phase profile of the circularly polarised red, green and blue light at each nanostructure. As will be explained herein, this causes the polarised light to be reflected and focused as the virtual image which may be observed by the receiver or user.

In some embodiments, the first surface of the lens is adjacent to the receiver. The second surface of the lens is thus positioned away from the receiver. The dielectric metasurface, being adjacent to the first surface, is thus sandwiched between the lens and the receiver. It was found that this arrangement allows for less distortion of the virtual image observed by the user as the circularly polarised light does not have to travel through the lens. Alternatively, the dielectric metasurface may be positioned away from the receiver on the second surface. However, correction of the distortion of virtual image should be accounted for and incorporated within the dielectric metasurface.

In some embodiments, the lens is a flat lens, converging lens or a diverging lens. In some embodiments, the converging lens is a double convex lens, a plano-convex lens or a converging meniscus lens. Other lens types may also be used, as long as the lens directs light to the receiver.

In some embodiments, the dielectric metasurface is adhered to the lens. This may be done via an adhesive. The adhesive is preferably a transparent adhesive, or one with a high transparency.

In some embodiments, the dielectric metasurface is characterised by a transparency of at least 90%. In other embodiments, the dielectric metasurface has a transparency of at least 91%, 92%, 93%, 94%, or 95%.

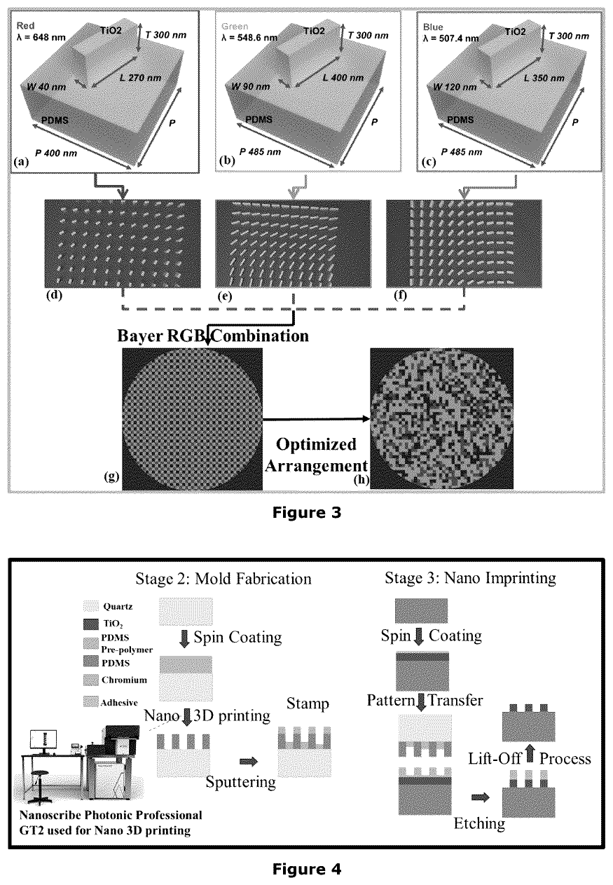

FIG. 3 shows examples of the nanostructures of the dielectric metasurface. The nanostructures may form an array on a surface of the polymer film. In some embodiments, the dielectric metasurface comprises at least three arrays of nanostructures, each of the at least three arrays of nanostructures configured to independently vary the phase profile of each of the circularly polarised red, green and blue light. In some embodiments, the dielectric metasurface comprises four arrays of nanostructures, each of the four arrays of nanostructures configured to independently vary the phase profile of each of the circularly polarised red, 1^{st} green, blue and 2^{nd} green light.

In some embodiments, the nanostructures in the at least three arrays are superimposed on each other. In some embodiments, the nanostructures in the at least three arrays are positioned adjacent to each other.

In some embodiments, the nanostructures in the at least three arrays of nanostructures are arrayed periodically or aperiodically.

In some embodiments, the nanostructures in the at least three arrays of nanostructures are arranged in a Bayer pattern or a random pattern. A Bayer filter mosaic is a color filter array for arranging RGB colour filters on a square grid of photosensors. Its particular arrangement of colour filters is used to create a colour image. The filter pattern is half green, one quarter red and one quarter blue, hence is also called BGGR, RGBG, GRBG, or RGGB.

In some embodiments, the at least three arrays of nanostructures are independently characterised by an emitted light with a hyperboloidal or parabolic phase profile.

In some embodiments, the polarised light is right circular polarised. In some embodiments, the polarised light is left circular polarised. The circularly polarised light may comprise a cross polarisation component and a co-polarisation component. In co-polarisation, the plane of linear polarisation is parallel to the transmitted light, whereas in cross-polarisation the plane of linear polarisation is perpendicular to the transmitted light. The circular polarization may be used to generate cross polarised and copolarised light component so that one polarisation can be reflected. In some embodiments, the dielectric metasurface is configured to vary the phase profile of a cross polarisation component of the circularly polarised red, green and blue light. In some embodiments, the phase profile of a co-polarisation component of the circularly polarised red, green and blue light is unaltered.

In some embodiments, the nanostructures are each characterised by a different orientation angle (θ) relative to each other. In some embodiments, the nanostructures are each characterised by an orientation angle (θ) dependent on its position on the dielectric metasurface.

In some embodiments, the nanostructures are each characterised by an orientation angle (θ) according to Formula (I):

$$Δ θ ( x , y ) = \frac{2 π}{λ} ( \sqrt{{x}^{2} + {y}^{2} - {f}^{2}} - f ) + \frac{2 π}{λ} x sin ( ∅ ) \qquad ( I )$$

wherein
x and y refers to a position of the nanostructure on the dielectric metasurface;
f is a focal length;
Ø is an oblique incidence of circularly polarised light; and
Λ is a wavelength of the circularly polarised light.

In some embodiments, the orientation angle of a nanostructure relative to another neighbouring nanostructure is about 0° to about 10°.

In some embodiments, each of the nanostructures is independently characterised by a morphology selected from a square, rectangle, ellipse, cross, hole, coaxial, ring, slit, or circle. In some embodiments, the nanostructures are rectangles.

In some embodiments, each of the nanostructures is independently characterised by a longitudinal axis of about 20 nm to about 380 nm. In some embodiments, each of the nanostructures is independently characterised by a transverse axis of about 20 nm to about 380 nm.

In some embodiments, when the array of nanostructures is configured to reflect and focus polarised red light, each of the nanostructure is characterised by a length of about 220 nm to about 300 nm. In some embodiments, the length is about 270 nm.

In some embodiments, when the array of nanostructures is configured to reflect and focus polarised red light, each of the nanostructure is characterised by a width of about 20 nm to about 60 nm. In some embodiments, the length is about 40 nm.

In some embodiments, when the array of nanostructures is configured to reflect and focus polarised red light, each of the nanostructure is characterised by a height of about 250 nm to about 350 nm. In some embodiments, the length is about 300 nm.

In some embodiments, when the array of nanostructures is configured to reflect and focus polarised green light, each of the nanostructure is characterised by a length of about 370 nm to about 420 nm. In some embodiments, the length is about 400 nm.

In some embodiments, when the array of nanostructures is configured to reflect and focus polarised green light, each of the nanostructure is characterised by a width of about 60 nm to about 100 nm. In some embodiments, the length is about 90 nm.

In some embodiments, when the array of nanostructures is configured to reflect and focus polarised green light, each of the nanostructure is characterised by a height of about 250 nm to about 350 nm. In some embodiments, the length is about 300 nm.

In some embodiments, when the array of nanostructures is configured to reflect and focus polarised blue light, each of the nanostructure is characterised by a length of about 300 nm to about 370 nm. In some embodiments, the length is about 350 nm.

In some embodiments, when the array of nanostructures is configured to reflect and focus polarised blue light, each of the nanostructure is characterised by a width of about 100 nm to about 150 nm. In some embodiments, the length is about 120 nm.

In some embodiments, when the array of nanostructures is configured to reflect and focus polarised blue light, each of the nanostructure is characterised by a height of about 250 nm to about 350 nm. In some embodiments, the length is about 300 nm.

In some embodiments, the nanostructures are characterised by a pitch (spacing between nanostructures) of about 20 nm to about 700 nm. In some embodiments, the pitch is about 490 nm.

In some embodiments, the nanostructures comprises a dielectric material and/or a metal, or is coated with a dielectric material and/or a metal. In some embodiments, the dielectric material and/or a metal is selected from titanium dioxide, silicon dioxide, silicon, germanium, magnesium fluoride, silver, gold, aluminium, and copper. The dielectric material may be titanium dioxide.

In some embodiments, the polymer film comprises polydimethylsiloxane (PDMS), polystyrenes, polycarbonates, cyclic olefin copolymer, polyesters (such as polyester optical plastic (OKP)) or a combination thereof.

For example, titanium dioxide (TiO₂) based meta atoms arranged on a PDMS substrate may be used. TiO₂ may be selected due to high transmission in the visible wavelength, low loss and high refractive index of around 2.6. The meta atoms consist of rectangular TiO₂ meta atoms with optimised width, length and height for reflecting red, green and blue (RGB) colours as shown in FIG. 3(a-c). The meta atoms are arranged to obtain a refractive index profile (phase profile) of a lens in reflection mode when incident at an oblique angle (FIG. 3(d-f)). The required phase retardation is a function of length, width, pitch, thickness and orientation angle of the meta atoms. An array of R, G and B is made separately and study their performance like reflection and focusing (focal length of each colour) of cross polarized light component as well as transmission percentage of the see-through co-polarized light component (FIG. 3(d-f)). Since the cross-polarized light coming through is normal to the surface (not at the oblique angle to behave as a lens like in the reflection mode), it will be least affected (see-through for almost all the unpolarized light). Using the optimisation algorithms, RGB meta atoms are combined starting from Bayer pattern (RGBG) to different arrangements (FIG. 3(g, h) by keeping the required phase profile to act as a reflective convex lens, while making the meta atoms maximum polarisation sensitive. Dedicated design/optimisation algorithms implemented in python together with optimisation modules in FEM based COMSOL Multiphysics may be used to get suitable phase profiles. Chromatic aberration (different focal lengths for R, G and B) will be corrected in the meta atoms design after measuring the focal lengths from the experiments. The oblique angle also will be optimised for the maximum reflection.

In some embodiments, the polymer film is characterised by a thickness of about 1 μm to about 10 mm. In other embodiments, the thickness is about 1 μm to about 9 mm, about 1 μm to about 8 mm, about 1 μm to about 6 mm, about 1 μm to about 5 mm, about 1 μm to about 4 mm, about 1 μm to about 2 mm, or about 1 μm to about 1 mm.

The meta atom may be further arranged to further correct for chromatic aberrations. Alternatively, another phase/optical element in the path near to projector may be used. The corrections may also be performed during image processing.

In some embodiments, the micro-display unit provides polarised light to the dielectric metasurface at an oblique angle. For example, the angle may be about 5° to about 80° relative to a plane of the dielectric metasurface.

In use, light (images) from a micro-display unit (light projector) will be rotated (right circularly polarised) using a waveplate integrated inside the projector and then will be directed from a fixed angle (oblique angle) to the AR meta atoms on the dielectric metasurface. The meta atoms will reflect and focus the cross polarised light component into the eye of the receiver (virtual image) as shown in FIG. 1(b). Lights from the outdoor real scenes will be transmitted through without any effect (see-through effect). FIG. 3 shows a schematic of this setup.

The presently disclosed display-combiner (meta AR) reduces eye strain due to the focusing of virtual image into the eye, reduce discomfort due to thin and flat display-combiner and increase of FOV due to the reflection from the large area. Since maximum polarised light is reflected by the meta atoms, the brightness of virtual image is enhanced without compromising transmitted light. The use of a transparent and flexible polymer will allow to integrate this technology to in very small curved applications like in helmets. Any slight potential distortions can be corrected in the meta atoms design together with standard real time image processing in the projector display.

The display-combiner may be fabricated using nano 3D printing and imprint lithography as shown in FIG. 4.

### Examples

### Optimisation of Metasurface Parameters

FIG. 3 shows the three meta-atoms or nanostructures (for example in rectangular shape) configured for reflecting red (R), green (G) and blue (B) light. The nanostructures may be configured be tuning the length (L) and width (W) of the nanostructured rectangle to obtain R, G and B reflected colours. The nanostructures may be coated with a dielectric material such as TiO₂, or may comprise the dielectric material. The thickness (T) along the vertical axis is kept constant (300 nm) for making fabrication less complex. Reflective meta lens for each R, G and B colour are designed (example, L=400 nm and W=90 for G) using an array of meta atoms to measure their characteristics. The phase profile was varied using different orientation angle for the meta atoms (θ). The meta atoms were fabricated on a 2-3 mm thick PDMS substrate. We use right circularly polarised light from a micro-display to fall on the meta lens of 1 cm×1 cm size. There are two polarisations considered here, co-polarisation and cross polarisation due to the longitudinal axis (L) and transverse or lateral axis (W) of the nano-rectangle (the meta atom).

The meta lens array may be designed by encoding a spatial phase profile for a converging lens with the focal length, f. We make the focal length approximately equal to eye relief ~10 mm. Suppose x and y are locations of the meta atoms on the PDMS sample along both x and y axis, then the required hyperboloidal phase profile can be realised using the below equation to ensure the constructive interference condition at the focal point for the reflected light. This can be obtained by changing the orientation angle (θ) of the meta atom for an oblique incidence of Ø.

$$Δ θ ( x , y ) = \frac{2 π}{λ} ( \sqrt{{x}^{2} + {y}^{2} - {f}^{2}} - f ) + \frac{2 π}{λ} x sin ( ∅ )$$

Here, the cross polarised light incident at angle Ø will experience the above phase profile and will be reflected and focused into the eye (virtual image). The spatial phase profile of the co-polarised transmitted light will be independent of the orientation angle of the meta atoms and hence it will be constant over the sample area. The cross polarised transmitted light incident normal to the surface will not be focused (Ø=0) in the equation. This might produce a negligible wavefront aberration only for the cross polarised component.

The RGB meta atoms are combined to form reflective meta lens for combined RGB. Optimisation algorithms may be used in order to obtain the desired phase profile and optimum performance: for example by placing RBG meta atoms side by side or a random arrangement. Hence, the meta AR acts like a transparent glass for the co-polarised transmission mode and acts as a convex lens for the reflected cross-polarised transmission mode. The length, width, pitch, thickness and orientation angle of the meta atoms may be optimised by putting constraints in the range of acceptable values. FIG. 6 shows some optimised different length and width combinations for obtaining different phase for both cross polarised and co-polarised lights.

Additionally, in relation to the see through light and thus transparency of the device, the cross polarised transmitted light will be incident normal to the surface of the meta lens and hence will not be focused (Ø=0) as per the equation. The co-polarised transmitted light is also incident normal to the surface of the meta lens and hence will not be focused.

A finite element method (COMSOL) may be used to design a single meta atom made of TiO₂ on PDMS surface for red green and blue light. The reflection, transmission, focussing and phase retardation profiles using a RGB meta atom as a unit cell in the simulation was studied. The optimised meta atoms array using the optimisation algorithms may then be imported to COMSOL for simulating the optical functions using high computing platform available at UoM.

### Fabrication of the Meta AR

### Stage 1—Optical Quality PDMS Substrate:

A PDMS layer of 2-3 mm thickness and 4 cm×4 cm is made using conventional molding technique. A 3D printed mold with inside surfaces covered using silicon wafers (after silanizing) of the suitable size is used for making the PDMS surfaces smooth. PDMS is poured and cured for making the PDMS substrate. Teflon is coated on the inside plastic mold for easy removal.

### Stage 2—Polymer Master for Meta Atoms:

A mold for making meta atoms is fabricated using Nanoscribe Photonic Professional GT2 (GT2). The 3D nanoscribe is a ‘high resolution printer’ that combines the technique of 2 photon polymerisation (2PP) with a traditional 3D printing workflow used for additive manufacturing. It offers a one-step process to fabricate almost any arbitrary complex 3D shapes and objects in 3D with nanoscale resolution over a large area. Furthermore, the nanoscribe can work with a large number of UV-sensitive materials that go beyond those commercially developed for this purpose (IP Photoresins® family). This includes other UV-cross-linkable polymers (i.e. SU-8 or hybrid organic-inorganic polymers), positive-tone photoresist. The nanoscribe has a resolution close to ~100 nm, over an area of 100×100 mm², maximum height of up to 10 mm and with writing speeds of up to 1 mm³ in 10 seconds. A polymer master with an active area of 1 cm×1 cm for meta atoms using the GT2 was made (FIG. 4).

### Stage 3—Nanoimprinting for Meta AR:

The developed polymer master is used to transfer the pattern to a PDMS matrix (stamp) and then will deposit chromium (Cr). TiO₂ is sputtered on the PDMS substrate (from stage 1) and then deposit an adhesion layer. The Cr coated PDMS stamp is used to imprint the TiO₂ meta atoms on the PDMS substrate using EVG 520 IS or EVG6200 at MCN (~minimum resolution 15 nm), followed by etching to make the Meta AR. The detailed steps are shown in FIG. 4.

Integrated Testing and Calibration of the Display-Combiner with Coupling Optics and Experimental Verification of Image Formation

Verification was obtained experimentally for the focal length, focal spot studies for co-polarised and cross polarized lights and MTF (modulation transfer function) of the meta lens. The reflection and focusing of the meta AR is investigated experimentally using a commercially available laser beam profiler with 248×248 2D focal plane array. The beam profile and focal spot is imaged using suitable polarisers to measure the percentage of reflection and transmission for co-polarisation and cross polarisation. Experiments were also done to measure focal length for R (660 nm), G (550 nm) and B (570 nm) colours and check if there is any chromatic aberration. This will also enable to measure the FOV.

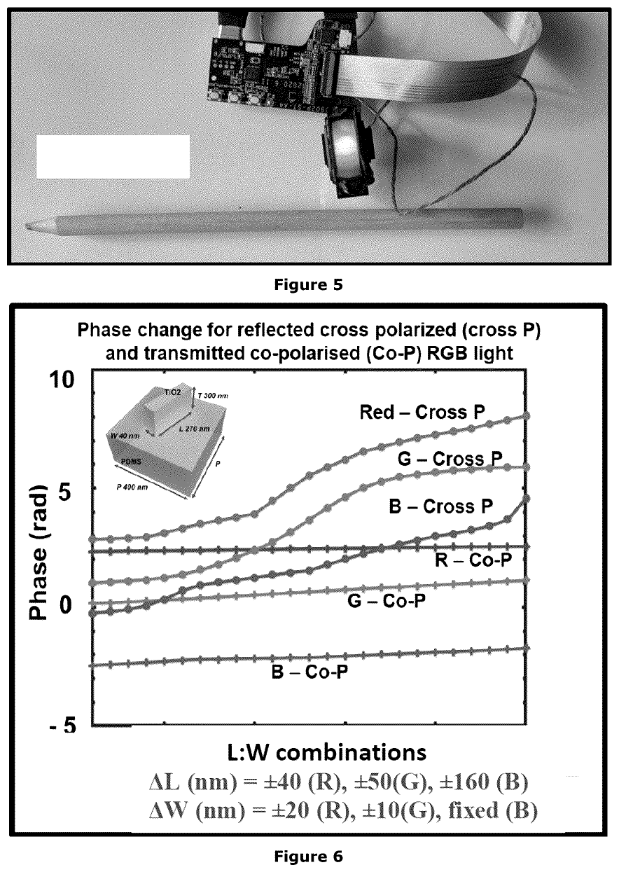

MTF of the meta lens is measured to find its ability to transfer contrast at a particular resolution from the object to the image using standard USAF pattern. MTF verses cycles per second is plotted using optical set up. FIG. 5 shows a lab-made micro-display-coupling optics (micro-projector) suitable for testing AR glasses (under research contracts) using commercially available LCOS display with resolution 1920×1080, FOV: 40° and size of 0.99 cm. The micro-projector is integrated with a waveplate for generating right circular polarized light. The entire mini-unit is attached on the side of a spectacle closer to the viewing area. The meta AR is used instead of the viewing glass on one side of the spectacle. The images from the projector will be projected at angle (Ø) to be reflected and focused into eye to see the virtual images. The Meta AR allows see through images. Any distortion produced by the system will be adjusted and corrected in the image-processing unit connected to the micro-display using standard video processing.

As a feasibility study, the TiO₂ meta atom parameters for reflecting R, G and B were estimated using algorithms (L=270 nm, 400 nm, 350, W=40 nm, 90 nm, 120 nm for R, G and B respectively). The thickness constant (300 nm) for all the meta-atoms for single step nanoimprint stage were kept constant. Different combinations of the L and W parameters were optimised (for example, in an array with different pitch (P) for obtaining different phase for both cross polarised (cross P) and co-polarised (co-P) lights. FIG. 6 shows the phase angle with respect to different L (L±ΔL) and W (W±ΔW) combinations for RGB for cross P (round dot) and co-P (cross shape) light components lights. The phase is almost constant for RGB co-polarised transmitted light (see-through). The phase is changed for RBG for cross polarised light and this may used to make a metalens. Further optimisation may be performed for more accurate combination of parameters such as L, W, P, Ø and θ to fine tune phase profile. Hence, the meta AR acts like a transparent glass for the co-polarised transmission mode and as a convex lens for the reflected cross-polarised transmission mode.

FIG. 7(a) shows a PDMS display film guiding image from a mobile phone display and then reflect to viewer's eyes without using any coupling optics between the display and the display film. The viewer's side (top side) where the phone symbol is displayed is made of a wedge shape with PDMS-air boundary to test the image formation. This was fabricated using a high-resolution 3D printed mold of the required shape and then poured engineered PDMS for better transparency, smoothness, flexibility (FIG. 7(b)) and uniform drying. This has proved the feasibility of using PDMS as an optical material for handling images like glasses.

An AR waveguide display-combiner using PDMS without any input image (FIG. 7(c)) and with input image coupled in (‘virtual image’) (FIG. 7(d)) are shown. Here, the image from a projector display (Pikachu in Pokemon) is coupled into the AR waveguide (tapered design) to undergo multiple reflections inside the waveguide before it is combined with the see-through object (mountain). The display-combiner is coated with nanoscale thick (~12 nm nm) gold pixels with size 50 μm and 20 μm pitch to tune reflection and transmission. Fresnel lenses using metasurfaces made of carbon nanotubes, electrical tuning of phase profile of nanophotonic lens array for 3D imaging, hologram pixels, cylindrical lenses using carbon nanotube based metasurfaces, wavefront aberration measurements in nanophotonic lenses, nanophotonic devices with multiple optical functionalities (grating and lens together with electrical reconfigurability), colour filters using metasurfaces and their integration on CMOS image sensors for multispectral imaging, plasmonic modulators using finite element methods (COMSOL), metasurfaces for on-chip spectral imaging, artificial intelligence, optimisation and machine learning for sensors and optical magnetic mirrors using metasurfaces are expected to work.

The presently disclosed display-combiner may be used to develop AR glasses resembling normal spectacles and AR motorcycle helmets. Using flexible PDMS as the substrate, this AR platform can be easily integrated with a motorcycle helmet to make an AR visor requiring a very small curvature with an active area of around 3 cm×3 cm as required. Any minor distortions in performance due to the curvature will be corrected in the arrangements of meta atoms. The present work may also improve the precision and accuracy of surgery by allowing surgeons to view previous scan results, organ models and data during operations. AR has many applications in across a range of educational settings. Medical students will be able to see organs as virtual images on a physical body during practicals. AR may support online education for children living in remote communities, or unable to physically attend school. The present invention promotes adoption by making AR headgear more comfortable to wear for longer periods of time.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

Throughout this specification and the claims which follow, unless the context requires otherwise, the phrase “consisting essentially of”, and variations such as “consists essentially of” will be understood to indicate that the recited element(s) is/are essential i.e. necessary elements of the invention. The phrase allows for the presence of other non-recited elements which do not materially affect the characteristics of the invention but excludes additional unspecified elements which would affect the basic and novel characteristics of the method defined.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A display-combiner for creating a virtual image observable by a receiver, comprising:
a) a lens having a first surface;
b) a dielectric metasurface adjacent to the first surface, the dielectric metasurface having a planar cross-sectional area extending over at least a portion of the first surface; and
c) a micro-display unit configured to provide circularly polarised red, green and blue light to the dielectric metasurface,
wherein the dielectric metasurface is a nanostructured polymer film configured to vary a phase profile of the circularly polarised red, green and blue light at each nanostructure in order for the polarised light to be reflected and focused as the virtual image to be observed by the receiver.

2. The display-combiner according to claim 1, wherein the first surface of the lens is adjacent to the receiver.

3. The display-combiner according to claim 1, wherein the lens is a flat lens, a metalens, a converging lens or a diverging lens, and wherein the converging lens is a double convex lens, a plano-convex lens or a converging meniscus lens.

4. The display-combiner according to claim 1, wherein the dielectric metasurface is adhered to the lens.

5. The display-combiner according to claim 1, wherein the dielectric metasurface comprises at least three arrays of nanostructures, each of the at least three arrays of nanostructures configured to independently vary the phase profile of each of the circularly polarised red, green and blue light, or wherein the dielectric metasurface comprises four arrays of nanostructures, each of the four arrays of nanostructures configured to independently vary the phase profile of each of the circularly polarised red, a first green, blue and a second green light.

6. The display-combiner according to claim 1, wherein the nanostructures in the at least three arrays of nanostructures are superimposed on each other.

7. The display-combiner according to claim 1, wherein the nanostructures in the at least three arrays of nanostructures are arranged in a Bayer pattern, a random pattern or semirandom pattern.

8. The display-combiner according to claim 1, wherein the at least three arrays of nanostructures are independently characterised by an emitted light with a hyperboloidal or parabolic phase profile.

9. The display-combiner according to claim 1, wherein the dielectric metasurface is configured to vary the phase profile of a cross polarisation component of the circularly polarised red, green and blue light.

10. The display-combiner according to claim 1, wherein the phase profile of a co-polarisation component of the circularly polarised red, green and blue light is unaltered.

11. The display-combiner according to claim 1, wherein the nanostructures are each characterised by an orientation angle (θ) according to Formula (I):
$$Δ θ ( x , y ) = \frac{2 π}{λ} ( \sqrt{{x}^{2} + {y}^{2} - {f}^{2}} - f ) + \frac{2 π}{λ} x sin ( ∅ ) \qquad ( I )$$
wherein
x and y refers to a position of the nanostructure on the dielectric metasurface;
f is a focal length;
Ø is an oblique incidence of circularly polarised light; and
Λ is a wavelength of the circularly polarised light.

12. The display-combiner according to claim 1, wherein an orientation angle of a nanostructure relative to another neighbouring nanostructure is about 0° to about 10°.

13. The display-combiner according to claim 1, wherein each of the nanostructures is independently characterised by a morphology selected from a square, rectangle, ellipse, cross, hole, coaxial, ring, slit, or circle.

14. The display-combiner according to claim 1, wherein each of the nanostructures is independently characterised by a longitudinal axis of about 20 nm to about 380 nm, and by a transverse axis of about 20 nm to about 380 nm; and
wherein the nanostructures are characterised by a pitch (spacing between nanostructures) of about 20 nm to about 700 nm.

15. The display-combiner according to claim 1, wherein when the array of nanostructures is configured to reflect and focus polarised red light, each of the nanostructure is characterised by a length of about 220 nm to about 300 nm, by a width of about 20 nm to about 60 nm, and by a height of about 250 nm to about 350 nm,
wherein when the array of nanostructures is configured to reflect and focus polarised green light, each of the nanostructure is characterised by a length of about 370 nm to about 420 nm, by a width of about 60 nm to about 100 nm, and by a height of about 250 nm to about 350 nm, and
wherein when the array of nanostructures is configured to reflect and focus polarised blue light, each of the nanostructure is characterised by a length of about 300 nm to about 370 nm, by a width of about 100 nm to about 150 nm, and by a height of about 250 nm to about 350 nm.

16. The display-combiner according to claim 1, wherein the nanostructures are characterised by a pitch (spacing between nanostructures) of about 20 nm to about 700 nm.

17. The display-combiner according to claim 1, wherein the nanostructures comprise a dielectric material and/or a metal, or is coated with a dielectric material and/or a metal, and
wherein the dielectric material and/or a metal is selected from titanium dioxide, silicon dioxide, silicon, germanium, magnesium fluoride, silver, gold, aluminium, and copper.

18. The display-combiner according to claim 1, wherein the nanostructured polymer film comprises polydimethylsiloxane (PDMS), polystyrenes, poly methyl methacrylate, polycarbonates, cyclic olefin copolymer, polyarylate, polyesters or a combination thereof.

19. The display-combiner according to claim 1, wherein the nanostructured polymer film is characterised by a thickness of about 1 μm to about 10 mm; and/or
wherein the dielectric metasurface is characterised by a transparency of at least 90%.

20. The display-combiner according to claim 1, wherein the micro-display unit provides polarised light to the metasurface at an oblique angle.

21. The display-combiner according to claim 1, wherein the polarised light is right circular polarised.
